(19) United States
(12) Patent Application Publication
(10) Pub. No.: US 2026/0068664 A1
(43) Pub. Date: Mar. 5, 2026

(54) PACKAGE STRUCTURE AND METHOD FOR MANUFACTURING SAME, AND ELECTRONIC DEVICE

(71) Applicant: CXMT Corporation, Hefei City (CN)

(72) Inventor: Xiaofei SUN, Hefei City (CN)

(73) Assignee: CXMT Corporation, Hefei City (CN)

(21) Appl. No.: 19/380,134

(22) Filed: Nov. 5, 2025

Related U.S. Application Data
(63) Continuation of application No. PCT/CN2023/135294, filed on Nov. 30, 2023.

(30) Foreign Application Priority Data
Nov. 17, 2023 (CN) 202311555124.1

(51) Int. Cl. H01L 23/373; H01L 23/00; H01L 23/31; H01L 25/065

(52) U.S. Cl. CPC H01L 23/3737

(57) ABSTRACT

A package structure and a method for manufacturing the same, and an electronic device are provided. The package structure includes a substrate, a chip stack, a heat dissipation layer, and a molding layer. The chip stack is disposed on the substrate, the heat dissipation layer is disposed on the chip stack, and the molding layer is disposed on the substrate and covers the chip stack. The molding layer is in contact with the heat dissipation layer, the molding layer and the heat dissipation layer are coplanar, and the thermal conductivity coefficient of the plastic encapsulating layer is less than the thermal conductivity coefficient of the heat dissipation layer.

### CROSS-REFERENCE TO RELATED APPLICATIONS

This application is a continuation of International Patent Application No. PCT/CN/2023/135294 field on Nov. 30, 2023, which claims priority to Chinese Patent Application No. 202311555124.1 filed on Nov. 17, 2023. The disclosures of the above-referenced applications are hereby incorporated by reference in their entirety.

### BACKGROUND

With the continuous development of semiconductor manufacturing technology and three-dimensional packaging technology, electronic products tend to be miniaturized and highly integrated, and the package size of chip is continuously reduced. Accordingly, the stacked die packaging technology emerges. The stacked die packaging technology, also referred to as a three-dimensional packaging technology, is a packaging technology in which two or more chips are stacked in a vertical direction in the same package structure. The package on package (Package on Package, PoP) is widely applied in various high-end portable electronic products, particularly in the packaging of mobile communication chips and memory chips, so as to meet their requirements for high-speed digital signal processing and memory response time. However, the heat dissipation performance of such a package structure is poor.

### SUMMARY

The present disclosure relates to the technical field of semiconductors, and in particular, to a package structure and a method for manufacturing the same, and an electronic device.

According to some embodiments, the present disclosure provides a package structure. The package structure includes:
a substrate;
a chip stack disposed on the substrate;
a heat dissipation layer disposed on the chip stack; and
a molding layer disposed on the substrate and covering the chip stack;
wherein the molding layer is in contact with the heat dissipation layer, the molding layer and the heat dissipation layer are coplanar, and a thermal conductivity coefficient of the molding layer is less than a thermal conductivity coefficient of the heat dissipation layer.

### BRIEF DESCRIPTION OF DRAWINGS

FIG. 1 is a first schematic diagram of a package structure according to an embodiment of the present disclosure;

FIG. 2 is a first schematic diagram of a chip stack according to an embodiment of the present disclosure;

FIG. 3 is a second schematic diagram of a chip stack according to an embodiment of the present disclosure;

FIG. 4 is a third schematic diagram of a chip stack according to an embodiment of the present disclosure;

FIG. 5 is a fourth schematic diagram of a chip stack according to an embodiment of the present disclosure;

FIG. 6 is a second schematic diagram of a package structure according to an embodiment of the present disclosure;

FIG. 7 is a third schematic diagram of a package structure according to an embodiment of the present disclosure;

FIG. 8 is a fourth schematic diagram of a package structure according to an embodiment of the present disclosure;

FIG. 9 is a fifth schematic diagram of a package structure according to an embodiment of the present disclosure;

FIG. 10 is a schematic diagram of a structure A according to an embodiment of the present disclosure;

FIG. 11 is a schematic diagram of a structure B according to an embodiment of the present disclosure;

FIG. 12 is a flowchart of a method for manufacturing a package structure according to an embodiment of the present disclosure;

FIG. 13 is a schematic diagram after forming a chip stack according to an embodiment of the present disclosure;

FIG. 14 is a schematic diagram after forming a heat dissipation layer according to an embodiment of the present disclosure;

FIG. 15 is a schematic diagram after forming a molding layer according to an embodiment of the present disclosure; and

FIG. 16 is a schematic diagram after thinning the molding layer according to an embodiment of the present disclosure.

### REFERENCE NUMERALS IN THE FIGURES ARE AS FOLLOWS

10, substrate; 11, substrate layer;
12, insulating layer; 13, connector;
14, connection pad; 15, connection post;
20, chip stack; 21, chip;
22, second adhesive layer; 30, heat dissipation layer;
31, main body portion; 32, extension portion;
33, through hole; 40, first adhesive layer;
50, molding layer; 60, connection block;
70, cooling plate; 80, transition layer.

### DESCRIPTION OF EMBODIMENTS

There is a problem in the prior art that the heat dissipation performance of the package structure is poor. After studies, the inventor finds that the reasons are as follows. The package structure includes a substrate, a chip stack disposed on the substrate, and a molding layer enveloping the chip stack. The region where the chip stack is in contact with the substrate is farthest away from the upper surface of the molding layer; the heat dissipation path is long, so heat in this region is not easily dissipated via the molding layer. Moreover, this region is in contact with the substrate, and the thermal conductivity of the substrate is poor, so heat in this region is not easily dissipated via the substrate, either. In the case that the temperature is high, the heat dissipation performance is poor.

The embodiments of the present disclosure provide a package structure. A heat dissipation layer is disposed on the chip stack, and the chip stack is covered with a molding layer. The molding layer is in contact with the heat dissipation layer, and the molding layer and the heat dissipation layer are coplanar. The heat dissipation layer is exposed and can be in contact with a medium such as air, and thus the heat dissipation performance can be improved; moreover, an increase in the height of the package structure can be avoided, thereby facilitating mounting of the package structure. The thermal conductivity coefficient of the molding layer is less than the thermal conductivity coefficient of the heat dissipation layer. The thermal conductivity coefficient of the heat dissipation layer is high, so that heat of the chip stack is directed primarily toward the heat dissipation layer for dissipation.

To make the above objectives, features, and advantages of the embodiments of the present disclosure clearer and more comprehensible, the technical solutions in the embodiments of the present disclosure will be clearly and comprehensively described hereinafter with reference to the accompanying drawings of the embodiments of the present disclosure. It is apparent that the described embodiments are only a part of the embodiments of the present disclosure rather than all embodiments. Based on the embodiments of the present disclosure, all other embodiments obtained by those of ordinary skill in the art without creative efforts shall fall within the protection scope of the present disclosure.

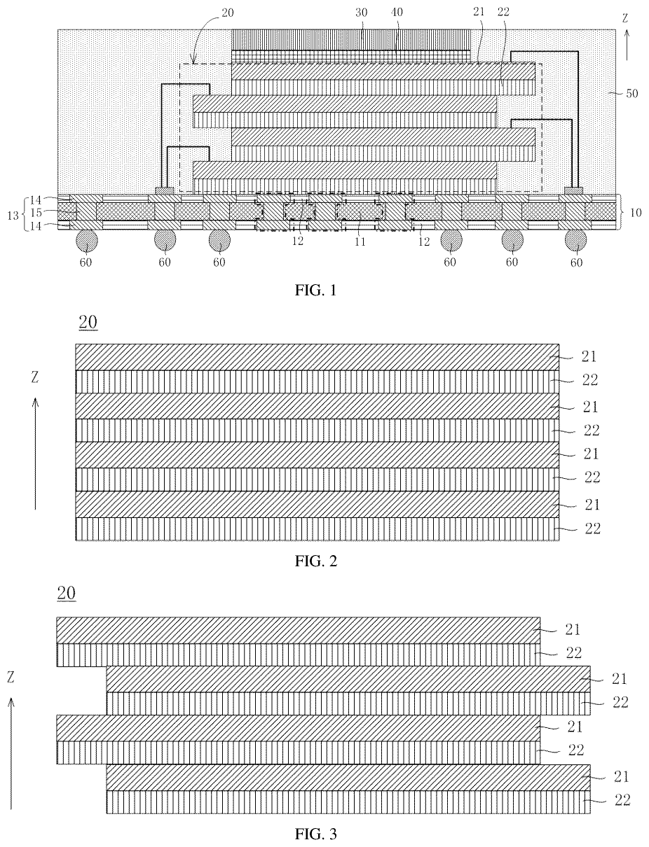

Referring to FIG. 1, the embodiments of the present disclosure provide a package structure. The package structure includes a substrate 10, a chip stack 20, a heat dissipation layer 30, and a molding layer 50. The substrate 10 provides support; the chip stack 20, the heat dissipation layer 30, and the molding layer 50 are disposed on the substrate 10.

The chip stack 20 is disposed on the substrate 10, the heat dissipation layer 30 is disposed on the chip stack 20, and the molding layer 50 is disposed on the substrate 10 and covers the chip stack 20, thereby enveloping the chip stack 20. The molding layer 50 is in contact with the heat dissipation layer 30, and the molding layer 50 and the heat dissipation layer 30 are coplanar, that is, a surface of the molding layer 50 that is away from the substrate 10 (i.e., the upper surface of the molding layer shown in FIG. 1) is flush with a surface of the heat dissipation layer 30 that is away from the substrate 10 (i.e., the upper surface of the heat dissipation layer shown in FIG. 1), and the thermal conductivity coefficient of the molding layer 50 is less than the thermal conductivity coefficient of the heat dissipation layer 30.

In this way, in one aspect, the heat dissipation layer 30 has a high thermal conductivity coefficient, so that heat of the chip stack 20 is directed primarily toward the heat dissipation layer 30 for dissipation; in another aspect, the molding layer 50 and the heat dissipation layer 30 are coplanar, so that the upper surface of the heat dissipation layer 30 is exposed and can be in contact with a medium such as air, and thus the heat dissipation performance can be improved; moreover, an increase of the height of the package structure can be avoided, thereby facilitating mounting of the package structure.

In some examples, the substrate 10 may include a substrate layer 11, and insulating layers 12 disposed on opposite surfaces of the substrate layer 11. As shown in FIG. 1, both the upper surface and the lower surface of the substrate layer 11 are each provided with the insulating layer 12. The insulating layer 12, the substrate layer 11, and the insulating layer 12 are stacked sequentially.

The material of the substrate layer 11 may be silicon, germanium, silicon-germanium, silicon carbide, silicon on insulator (Silicon On Insulator, SOI), germanium on insulator (Germanium On Insulator, GOI), gallium nitride, gallium arsenide, or the like. The material of the insulating layer 12 may be green paint.

The substrate 10 further includes a connector 13 disposed in the substrate 10, and two opposite surfaces of the connector 13 are exposed on two opposite surfaces of the substrate 10, respectively. As shown in FIG. 1, the upper surface of the connector 13 is exposed on the upper surface of the substrate 10, and the lower surface of the connector 13 is exposed on the lower surface of the substrate 10. In this way, two opposite surfaces of the connector 13 can be conveniently connected to the chip stack 20 and other structures, respectively, so as to realize signal transmission between the chip stack 20 and other structures. Illustratively, two opposite surfaces of the connector 13 are connected to the chip stack 20 and a system on a chip (System on a Chip, SOC), respectively, to form a package on package.

In some possible implementations, the connector 13 includes connection pads 14 that are disposed in two insulating layers 12, respectively, and a connection post 15 that is disposed in the substrate layer 11 and connects two opposite connection pads 14. The material of the connection pad 14 may be aluminum, copper, nickel, tungsten, platinum, gold, or an alloy thereof, and the connection post 15 may be a through silicon via (Through Silicon Via, TSV).

To facilitate the connection between the substrate 10 and a structure such as a SOC, the package structure further includes a connection block 60. The connection block 60 is disposed on a surface of the substrate 10 that is away from the chip stack 20; that is, the connection block 60 and the chip stack 20 are located on two sides of the substrate 10, respectively. The connection block 60 is also in contact with the connector 13, and at least a part of the connectors 13 are each correspondingly provided with the connection block 60. The connection blocks 60 may be solder balls, and the number, spacing, and positions of the solder balls are not limited to any particular arrangement.

It can be understood that the number of the connection blocks 60 is less than or equal to the number of the connectors 13. In some possible examples, a plurality of connectors 13 include real connectors and virtual connectors. The connectors 13 in contact with the connection blocks 60 are all real connectors, and perform circuit connection and signal transmission via the connection blocks 60. The connector 13 not in contact with the connection block 60 is a virtual connector. As shown in the dashed box in FIG. 1, the virtual connector is not connected to a circuit and does not perform signal transmission; the virtual connector is located below the chip stack 20 as an independent component, so that heat of the chip stack 20 can be dissipated from the virtual connector, thereby reducing upward heat transfer.

With continued reference to FIG. 1, the chip stack 20 is disposed on the substrate 10, and the chip stack 20 includes at least two chips 21. The chip 21 includes a dynamic random access memory (Dynamic Random Access Memory, DRAM) chip, a static random access memory (Static Random Access Memory, SRAM) chip, an electrically erasable programmable read only memory (Electrically Erasable Programmable Read Only Memory, EEPROM) chip, a magnetic random access memory (Magnetic Random Access Memory, MRAM) chip, a resistive random access memory (Resistive Random Access Memory, RRAM) chip, and the like.

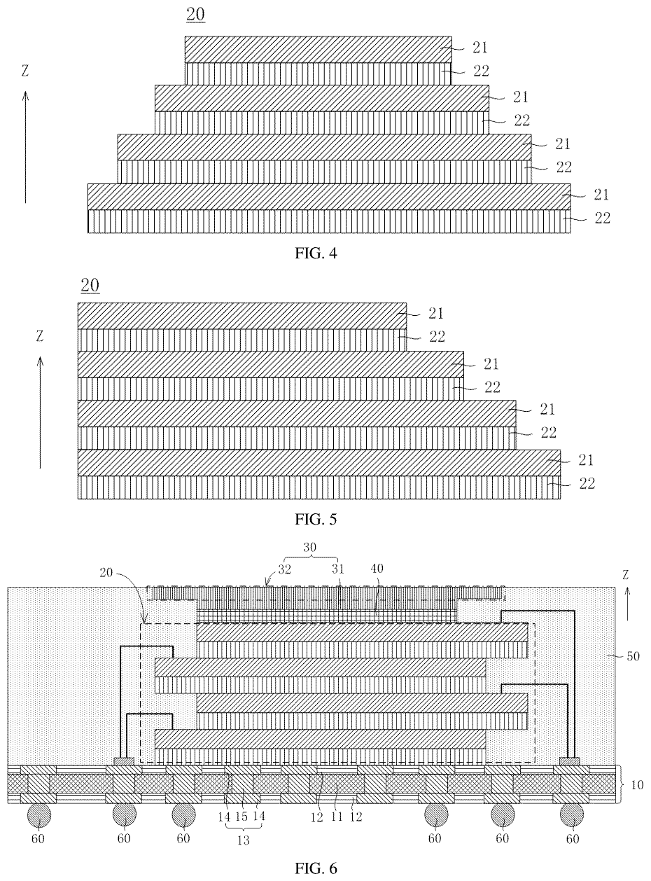

The at least two chips 21 are stacked sequentially in a direction away from the substrate 10. The stacking direction of the at least two chips 21 is the vertical direction (Z direction) shown in FIG. 1. The stacking manner of the at least two chips 21 includes an aligned manner, a staggered manner, a pyramid manner, or a stepped manner. Referring to FIG. 2, a plurality of chips 21 are stacked in an aligned manner, and edges of the plurality of chips 21 are aligned. Referring to FIG. 3, a plurality of chips 21 are stacked in a staggered manner, two adjacent chips 21 are offset relative to each other, and two chips 21 in every other layer are aligned with each other. Referring to FIG. 4, a plurality of chips 21 are stacked in a pyramid manner. In two adjacent chips 21, the chip 21 away from the substrate 10 is located in the middle of the chip 21 close to the substrate 10, and circumferential edges of the chip 21 close to the substrate 10 are exposed. Referring to FIG. 5, a plurality of chips 21 are stacked in a stepped manner. One end of each of the plurality of chips 21 is aligned, and the opposite ends thereof form steps. In two adjacent chips 21, one end of the chip 21 close to the substrate 10 is exposed.

A second adhesive layer 22 is provided between two adjacent chips 21 to bond the chips 21, thereby improving the stability of the chip stack 20. The second adhesive layer 22 may be a die attach film (Die Attach Film, DAF), and the die attach film corresponds to the chip 21, that is, a surface of each chip 21 that faces the substrate 10 (i.e., the lower surface of the chip) is correspondingly provided with a die attach film.

The shape of the die attach film matches the shape of a corresponding chip 21, and the size of the die attach film matches the size of a corresponding chip 21. Illustratively, as shown in FIGS. 1 to 5, edges of a chip 21 and a die attach film that correspond to each other are aligned, and the orthographic projection of a chip 21 on the substrate 10 coincides with the orthographic projection of a corresponding second adhesive layer 22 on the substrate 10.

In this way, the chip 21 and the corresponding die attach film may be formed by dicing. During the dicing, the chip 21 and the corresponding die attach film remain in contact and are not separated, thereby preventing the chip 21 and the corresponding die attach film from being scattered.

Each chip 21 is further electrically connected to the substrate 10. Illustratively, referring to FIG. 1, each chip 21 is electrically connected to the substrate 10 by wire bonding, and the material of the wire may be at least one of a copper alloy and an iron-nickel alloy.

With continued reference to FIG. 1, the heat dissipation layer 30 is disposed on the chip stack 20 and is in contact with the chip stack 20, so as to dissipate heat from the chip stack 20. The elastic modulus of the heat dissipation layer 30 is greater than the elastic modulus of the molding layer 50. The elastic modulus of the heat dissipation layer 30 is high; the heat dissipation layer is not prone to deformation. The coefficient of thermal expansion (CTE) of the heat dissipation layer 30 is less than the CTE of the molding layer 50. The CTE of the heat dissipation layer 30 is low; the heat dissipation layer is not prone to volume change, thereby reducing the possibility of warpage of the heat dissipation layer 30. Illustratively, the material of the heat dissipation layer 30 includes silicon, thereby improving the heat dissipation performance while reducing costs; the material of the molding layer 50 is a resin including a filler.

The heat dissipation layer 30 and the chip stack 20 are fixed relative to each other, so as to ensure reliable contact between the heat dissipation layer 30 and the chip stack 20 and prevent the heat dissipation layer 30 and the chip stack 20 from separating. Illustratively, the heat dissipation layer 30 is disposed on the chip stack 20 via a first adhesive layer 40; the first adhesive layer 40 is disposed on a surface of the chip stack 20 that is away from the substrate 10 (i.e., the upper surface of the chip stack shown in FIG. 1), and the heat dissipation layer 30 is disposed on a surface of the chip stack 20 that is away from the substrate 10 (i.e., the upper surface of the chip stack shown in FIG. 1), that is, the chip stack 20, the first adhesive layer 40, and the heat dissipation layer 30 are stacked sequentially in a direction away from the substrate 10.

The outer peripheral surface of the heat dissipation layer 30 protrudes from or coincides with the outer peripheral surface of the first adhesive layer 40; the orthographic projection of the heat dissipation layer 30 on the substrate 10 covers the orthographic projection of the first adhesive layer 40 on the substrate 10, or coincides with the orthographic projection of the first adhesive layer 40 on the substrate 10. In this way, the heat dissipation layer 30 can dissipate heat from the entire upper surface of the first adhesive layer 40, thereby improving the heat dissipation performance.

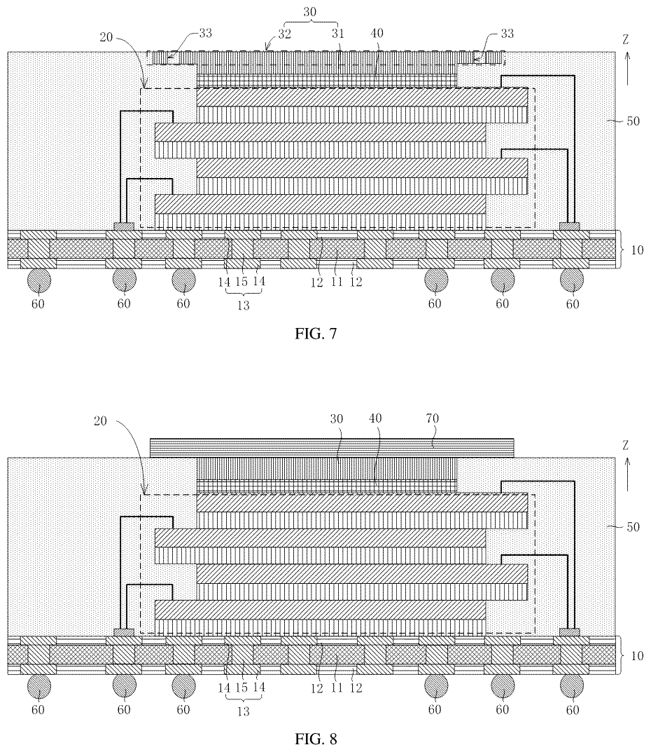

In some examples, referring to FIGS. 6 and 7, the heat dissipation layer 30 includes a main body portion 31 and an extension portion 32, the main body portion 31 is in contact with the first adhesive layer 40, the extension portion 32 is connected to the upper surface of the main body portion 31 and extends toward the outer side of the main body portion 31, and a part of the molding layer 50 is located between the extension portion 32 and the chip stack 20. The extension portion 32 is located on a side of the main body portion 31 that is away from the substrate 10, and the outer peripheral surface of the extension portion 32 protrudes from the outer peripheral surface of the main body portion 31 to increase the area of the extension portion 32, thereby increasing the heat dissipation area of the heat dissipation layer 30 and thus improving the heat dissipation performance.

The extension portion 32 and the main body portion 31 may be an integrated structure. The main body portion 31 may be adapted to the first adhesive layer 40, that is, edges of the main body portion 31 are aligned with edges of the first adhesive layer 40, so that the contact area between the main body portion 31 and the first adhesive layer 40 is large, thereby facilitating adhesion.

As shown in FIG. 6, a chip 21, which is correspondingly connected to the first adhesive layer 40 in the chip stack 20, (i.e., the chip 21 that is farthest away from the substrate 10), is provided with a connecting structure, such as a wire. The outer peripheral surface of the first adhesive layer 40 is recessed into the outer peripheral surface of the chip 21, that is, the area of the first adhesive layer 40 is small. The main body portion 31 is correspondingly connected to the first adhesive layer 40, and the heat dissipation area of the main body portion 31 can be increased. The extension portion 32 extends toward the outer side of the main body portion 31, and the heat dissipation area of the extension portion 32 can be further increased, so that the heat dissipation performance of the heat dissipation layer 30 is good.

In some examples, as shown in FIG. 7, the extension portion 32 further includes through holes 33, and a part of the molding layer 50 is located within the through holes 33. When molding is performed, the molding layer 50 flows from top to bottom, and the extension portion 32 blocks the molding layer 50 from flowing downward. By providing the through hole 33 in the extension portion 32, the molding layer 50 can flow downward via the through hole 33. This results in good fluidity and thereby reduces and prevents the formation of voids in the molding layer 50, so that the molding performance is good. Illustratively, the through holes 33 are arranged in a row.

With continued reference to FIGS. 6 and 7, the thickness of the first adhesive layer 40 is less than the thickness of the second adhesive layer 22. The first adhesive layer 40 is thin and transfers heat fast. The side wall of the first adhesive layer 40 is in contact with the molding layer 50, and the thermal conductivity coefficient of the first adhesive layer 40 is greater than the thermal conductivity coefficient of the molding layer 50, so that heat of the chip stack 20 is directed primarily toward the first adhesive layer 40 for dissipation.

Both the first adhesive layer 40 and the molding layer 50 include a base material and a filler. The base materials of the first adhesive layer 40 and the molding layer 50 may be of the same type; for example, both are resins. The first adhesive layer 40 and the molding layer 50 are different in at least one of filler type, filler content, and filler volume, so that the first adhesive layer 40 and the molding layer 50 have different thermal conductivity coefficients. The filler is silicon oxide, aluminum oxide, graphene, or the like.

In some examples, the filler content of the first adhesive layer 40 is greater than the filler content of the molding layer 50. The thermal conductivity of the base material is poor; the filler can improve the thermal conductivity of the base material. The more the filler, the better the thermal conductivity. The filler volume of the first adhesive layer 40 is greater than the filler volume of the molding layer 50. The smaller the filler volume, the higher the fluidity of the molding layer 50, so that when the molding layer 50 (e.g., the resin in the molding layer) flows downward, the fluidity becomes higher, and the through hole 33 and the region between the extension portion 32 and the chip stack 20 can be better filled, thereby effectively reducing the probability of void formation during filling.

To further improve the heat dissipation performance of the package structure, referring to FIG. 8, in some examples, the package structure further includes a cooling plate 70. The cooling plate 70 is located on the heat dissipation layer 30 and the molding layer 50, and the contact area between the cooling plate 70 and the heat dissipation layer 30 is greater than the contact area between the cooling plate 70 and the molding layer 50. By increasing the contact area between the cooling plate 70 and the heat dissipation layer 30, the heat dissipation of the heat dissipation layer 30 is accelerated, thereby further improving the heat dissipation performance.

The thermal conductivity coefficient of the cooling plate 70 is greater than the thermal conductivity coefficient of the heat dissipation layer 30, so that heat is directed primarily toward the cooling plate 70 of the heat dissipation layer 30 for dissipation. The elastic modulus of the cooling plate 70 is greater than the elastic modulus of the heat dissipation layer 30, so that the deformation of the cooling plate 70 is reduced. The CTE of the cooling plate 70 is less than the CTE of the heat dissipation layer 30, so that the volume change of the cooling plate 70 is reduced, and the warpage of the cooling plate 70 is avoided. Illustratively, the cooling plate 70 may be a metal plate.

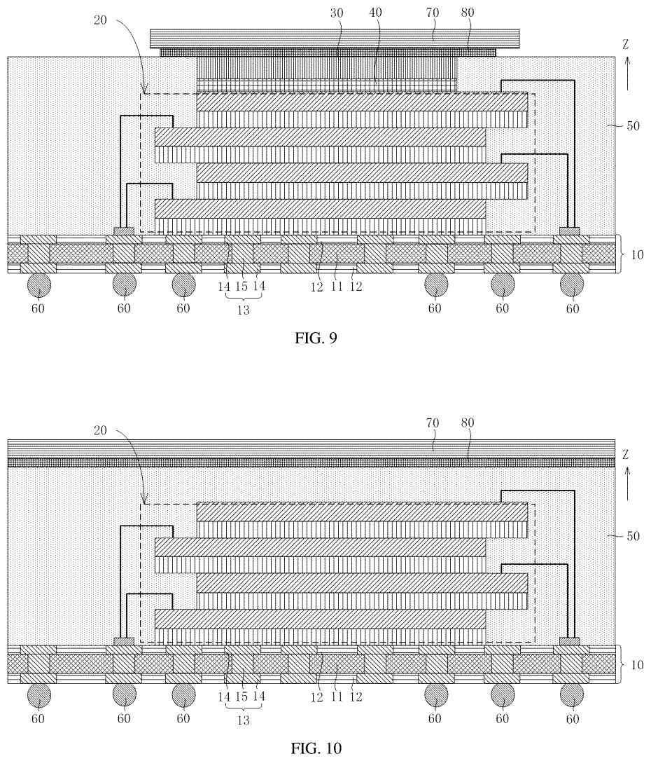

In some other examples, referring to FIG. 9, the package structure further includes a cooling plate 70 and a transition layer 80. The transition layer 80 is located on the heat dissipation layer 30 and the molding layer 50, and the contact area between the transition layer 80 and the heat dissipation layer 30 is greater than the contact area between the cooling plate 70 and the molding layer 50. The cooling plate 70 is disposed on the transition layer 80 and extends toward the outer side of the transition layer 80.

The thermal conductivity coefficient of the transition layer 80 is greater than or equal to the thermal conductivity coefficient of the heat dissipation layer 30, and less than the thermal conductivity coefficient of the cooling plate 70; the elastic modulus of the transition layer 80 is less than or equal to the elastic modulus of the cooling plate 70, and greater than the elastic modulus of the heat dissipation layer 30; the CTE of the transition layer 80 is greater than or equal to the CTE of the cooling plate 70, and less than the CTE of the heat dissipation layer 30. The transition layer 80 may be a thermal interface material.

In this way, in a direction away from the substrate 10, the thermal conductivity coefficients of the molding layer 50, the transition layer 80, and the cooling plate 70 gradually increase, the elastic moduli of the molding layer 50, the transition layer 80, and the cooling plate 70 gradually increase, and the CTEs of the molding layer 50, the transition layer 80, and the cooling plate 70 gradually decrease, so as to match the cooling plate 70 and the heat dissipation layer 30 as well as the cooling plate 70 and the molding layer 50, thereby avoiding warpage and separation of the transition layer 80 and the cooling plate 70.

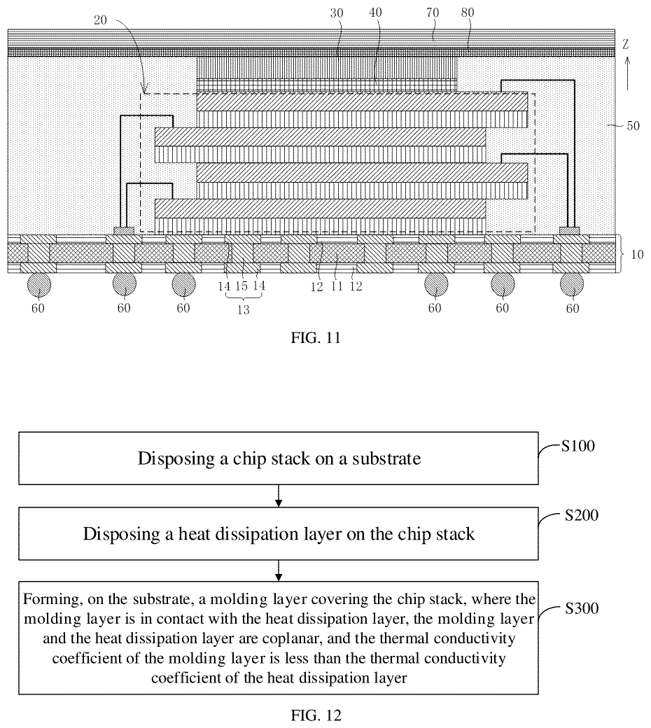

Referring to FIGS. 10 and 11, thermal simulation is performed on the structure A shown in FIG. 10 and the structure B shown in FIG. 11. On the basis of consistency of other parameters such as size and material, the maximum temperature of the chip 21 in the chip stack 20 of the structure A is 85.705° C., the maximum temperature of the chip 21 in the chip stack 20 of the structure B is 79.291° C., and the point with the maximum temperature is located on the chip 21 closest to the substrate 10 and is close to the right end of the chip 21. Compared with the structure A, the maximum temperature of the structure B is reduced by 7.4838%; the heat dissipation performance of the structure B is good.

In summary, the package structure according to the embodiments of the present disclosure includes the substrate 10, the chip stack 20, the heat dissipation layer 30, and the molding layer 50. The chip stack 20 is disposed on the substrate 10, the heat dissipation layer 30 is disposed on the chip stack 20, and the molding layer 50 is disposed on the substrate 10 and covers the chip stack 20. The molding layer 50 is in contact with the heat dissipation layer 30, and the molding layer 50 and the heat dissipation layer 30 are coplanar. In one aspect, the heat dissipation layer 30 is exposed and can be in contact with a medium such as air, so that the heat dissipation performance can be improved; in another aspect, an increase in the height of the package structure can be avoided, thereby facilitating mounting of the package structure. The thermal conductivity coefficient of the molding layer 50 is less than the thermal conductivity coefficient of the heat dissipation layer 30. The thermal conductivity coefficient of the heat dissipation layer 30 is high, so that heat of the chip stack 20 is directed primarily toward the heat dissipation layer 30 for dissipation.

The embodiments of the present disclosure further provide an electronic device. The electronic device includes the package structure as described above. The electronic device includes, but is not limited to, a server, a printer, a scanner, a tablet computer, a smartphone, a driving recorder, a navigation device, a wearable device, and the like. The electronic device includes the package structure as described above, and thus has at least the advantage of good heat dissipation performance. For specific effects, reference can be made to the foregoing description, which will not be described here again.

The embodiments of the present disclosure further provide a method for manufacturing a package structure. Referring to FIG. 12, the manufacturing method includes the following steps.

In step S100, a chip stack is disposed on a substrate.

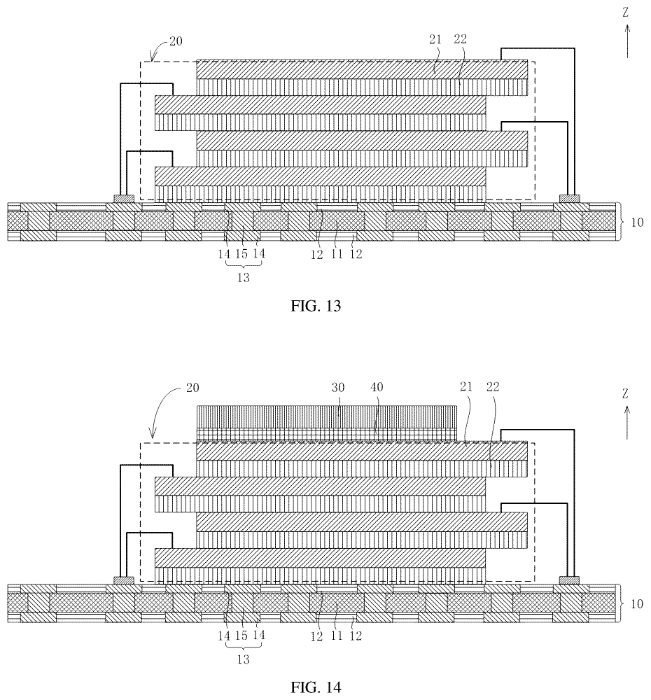

Referring to FIG. 13, a chip stack 20 is fixed on a substrate 10 and is electrically connected to the substrate 10. For example, the chip stack 20 is wire-bonded to the substrate 10. The chip stack 20 includes at least two chips 21, and the at least two chips 21 are stacked sequentially in a direction away from the substrate 10. The stacking direction of the at least two chips 21 is the vertical direction (Z direction) shown in FIG. 13.

The stacking manner of the at least two chips 21 includes an aligned manner, a staggered manner, a pyramid manner, or a stepped manner. Referring to FIG. 2, a plurality of chips 21 are stacked in an aligned manner, and edges of the plurality of chips 21 are aligned. Referring to FIG. 3, a plurality of chips 21 are stacked in a staggered manner, two adjacent chips 21 are offset relative to each other, and two chips 21 in every other layer are aligned with each other. Referring to FIG. 4, a plurality of chips 21 are stacked in a pyramid manner. In two adjacent chips 21, the chip 21 away from the substrate 10 is located in the middle of the chip 21 close to the substrate 10, and circumferential edges of the chip 21 close to the substrate 10 are exposed. Referring to FIG. 5, a plurality of chips 21 are stacked in a stepped manner. One end of each of the plurality of chips 21 is aligned, and the opposite ends thereof form steps. In two adjacent chips 21, one end of the chip 21 close to the substrate 10 is exposed.

A second adhesive layer 22 is provided between two adjacent chips 21 to bond the chips 21, thereby improving the stability of the chip stack 20. The second adhesive layer 22 may be a die attach film. The die attach film corresponds to the chip 21, that is, a surface of each chip 21 that faces the substrate 10 (i.e., the lower surface of the chip shown in FIG. 13) is correspondingly provided with a die attach film. The die attach film on the lower surface of the chip 21 that is closest to the substrate 10 is correspondingly connected to the chip 21 and the substrate 10, thereby fixing the chip stack 20 on the substrate 10.

The shape of the die attach film matches the shape of a corresponding chip 21, and the size of the die attach film matches the size of a corresponding chip 21. Illustratively, edges of a chip 21 and a die attach film that correspond to each other are aligned, that is, the orthographic projection of the chip 21 on the substrate 10 covers the orthographic projection of the corresponding second adhesive layer 22 on the substrate 10.

In this way, the chip 21 and the corresponding die attach film may be formed by dicing. During the dicing, the chip 21 and the corresponding die attach film remain in contact and are not separated, thereby preventing the chip 21 and the corresponding die attach film from being scattered.

In step S200, a heat dissipation layer is disposed on the chip stack.

Referring to FIG. 14, a heat dissipation layer 30 is disposed on the chip stack 20 via a first adhesive layer 40, that is, the chip stack 20, the first adhesive layer 40, and the heat dissipation layer 30 are stacked sequentially. The outer peripheral surface of the heat dissipation layer 30 may be aligned with the outer peripheral surface of the first adhesive layer 40, so as to increase the contact area between the heat dissipation layer 30 and the first adhesive layer 40. The material of the heat dissipation layer 30 includes silicon, thereby improving the heat dissipation performance while reducing costs.

In step S300, a molding layer covering the chip stack is formed on the substrate. The molding layer is in contact with the heat dissipation layer, the molding layer and the heat dissipation layer are coplanar, and the thermal conductivity coefficient of the molding layer is less than the thermal conductivity coefficient of the heat dissipation layer.

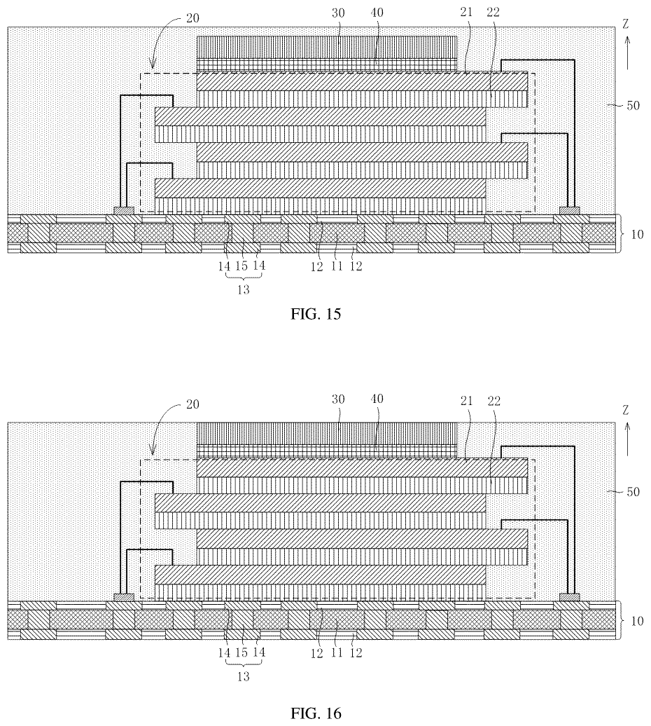

Referring to FIGS. 15 and 16, a molding layer 50 is formed. The molding layer 50 is located on the substrate 10 and covers the chip stack 20. The molding layer 50 is in contact with the heat dissipation layer 30, the molding layer 50 and the heat dissipation layer 30 are coplanar, and the thermal conductivity coefficient of the molding layer 50 is less than the thermal conductivity coefficient of the heat dissipation layer 30. In one aspect, the heat dissipation layer 30 has a high thermal conductivity coefficient, so that heat of the chip stack 20 is directed primarily toward the heat dissipation layer 30 for dissipation. In another aspect, the molding layer 50 and the heat dissipation layer 30 are coplanar, and the heat dissipation layer 30 is exposed and can be in contact with a medium such as air, so that the heat dissipation performance can be improved; moreover, an increase in the height of the package structure can be avoided, thereby facilitating mounting of the package structure.

In some examples, the elastic modulus of the heat dissipation layer 30 is greater than the elastic modulus of the molding layer 50. The elastic modulus of the heat dissipation layer 30 is high; the heat dissipation layer is not prone to deformation. The CTE of the heat dissipation layer 30 is less than the CTE of the molding layer 50. The CTE of the heat dissipation layer 30 is low; the heat dissipation layer is not prone to volume change, thereby reducing the possibility of warpage of the heat dissipation layer 30. The side wall of the first adhesive layer 40 is in contact with the molding layer 50, and the thermal conductivity coefficient of the first adhesive layer 40 is greater than the thermal conductivity coefficient of the molding layer 50, so that heat of the chip stack 20 is directed primarily toward the first adhesive layer 40 for dissipation.

Both the first adhesive layer 40 and the molding layer 50 include a base material and a filler. The base materials of the first adhesive layer 40 and the molding layer 50 may be of the same type; for example, both are resins. The first adhesive layer 40 and the molding layer 50 are different in at least one of filler type, filler content, and filler volume, so that the first adhesive layer 40 and the molding layer 50 have different thermal conductivity coefficients. The filler is silicon oxide, aluminum oxide, graphene, or the like.

In some examples, the filler content of the first adhesive layer 40 is greater than the filler content of the molding layer 50. The thermal conductivity of the base material is poor; the filler can improve the thermal conductivity of the base material. The more the filler, the better the thermal conductivity. The filler volume of the first adhesive layer 40 is greater than the filler volume of the molding layer 50. The smaller the filler volume, the higher the fluidity of the molding layer 50 (e.g., a resin in the molding layer), so that the molding capability of the molding layer 50 can be improved, and the probability of void formation can be reduced.

In some possible implementations, forming the molding layer 50 on the substrate 10 (step S300) includes: referring to FIG. 15, forming the molding layer 50, where the molding layer 50 envelops the chip stack 20 and the heat dissipation layer 30; referring to FIG. 16, thinning the molding layer 50 to expose the heat dissipation layer 30, where the surface of the heat dissipation layer 30 that is away from the substrate 10 is aligned with the surface of the remaining molding layer 50 that is away from the substrate 10. By forming the molding layer 50 and then thinning the molding layer 50, for example, by strip grinding, the existing processes and device capabilities can be fully utilized.

Referring to FIG. 16, after forming the molding layer 50 on the substrate 10 (step S300), the manufacturing method further includes: forming a connection block 60 on a surface of the substrate 10 that is away from the molding layer 50, where the connection block 60 is electrically connected to the substrate 10. The connection block 60 may be a solder ball, and the material of the solder ball may be copper or an alloy thereof.

In summary, in the method for manufacturing a package structure according to the embodiments of the present disclosure, the chip stack 20 is disposed on the substrate 10, the heat dissipation layer 30 is disposed on the chip stack 20, and the molding layer 50 covering the chip stack 20 is formed on the substrate 10. The molding layer 50 is in contact with the heat dissipation layer 30, and the molding layer 50 and the heat dissipation layer 30 are coplanar, so that the heat dissipation layer 30 is exposed and can be in contact with a medium such as air, and thus the heat dissipation performance can be improved; moreover, an increase in the height of the package structure can be avoided, thereby facilitating mounting of the package structure. The thermal conductivity coefficient of the molding layer 50 is less than the thermal conductivity coefficient of the heat dissipation layer 30. The thermal conductivity coefficient of the heat dissipation layer 30 is high, so that heat of the chip stack 20 is directed primarily toward the heat dissipation layer 30 for dissipation.

In this specification, each embodiment or implementation is described in a progressive manner, and each embodiment focuses on the differences from other embodiments. The similar or identical parts between the embodiments can be referred to interchangeably. Description with reference to the term “an embodiment”, “some embodiments”, “illustrative embodiments”, “example”, “specific example”, “some examples”, or the like means that a specific feature, structure, material, or characteristic described in conjunction with the embodiment or example is included in at least one embodiment or example of the present disclosure. In this specification, the illustrative description of the above terms does not necessarily refer to the same embodiment or example. Moreover, the specific feature, structure, material, or characteristic described may be combined in a suitable manner in any one or more embodiments or examples.

Finally, it should be noted that the above embodiments are merely used to illustrate the technical solutions of the present disclosure, rather than limiting them. Although the present disclosure has been described in detail with reference to the above embodiments, those of ordinary skill in the art should understand that they can still make modifications to the technical solutions described in the above embodiments or make equivalent replacements for some or all of the technical features. These modifications or replacements do not cause the essence of the corresponding technical solutions to depart from the scope of the technical solutions of the embodiments of the present disclosure.

What is claimed is:

1. A package structure, comprising:
a substrate;
a chip stack disposed on the substrate;
a heat dissipation layer disposed on the chip stack; and
a molding layer disposed on the substrate and covering the chip stack;
wherein the molding layer is in contact with the heat dissipation layer, the molding layer and the heat dissipation layer are coplanar, and a thermal conductivity coefficient of the molding layer is less than a thermal conductivity coefficient of the heat dissipation layer.

2. The package structure according to claim 1, wherein an elastic modulus of the heat dissipation layer is greater than an elastic modulus of the molding layer.

3. The package structure according to claim 1, wherein a coefficient of thermal expansion (CTE) of the heat dissipation layer is less than a CTE of the molding layer.

4. The package structure according to claim 1, wherein the heat dissipation layer is disposed on the chip stack via a first adhesive layer.

5. The package structure according to claim 4, wherein a side wall of the first adhesive layer is in contact with the molding layer, and a thermal conductivity coefficient of the first adhesive layer is greater than the thermal conductivity coefficient of the molding layer.

6. The package structure according to claim 4, wherein a filler content of the first adhesive layer is greater than a filler content of the molding layer.

7. The package structure according to claim 4, wherein a filler volume of the first adhesive layer is greater than a filler volume of the molding layer.

8. The package structure according to claim 4, wherein the heat dissipation layer comprises:
a main body portion in contact with the first adhesive layer; and
an extension portion connected to an upper surface of the main body portion and extending toward an outer side of the main body portion;
wherein a part of the molding layer is located between the extension portion and the chip stack.

9. The package structure according to claim 8, further comprising a cooling plate, wherein the cooling plate is located on the heat dissipation layer and the molding layer, and a contact area between the cooling plate and the heat dissipation layer is greater than a contact area between the cooling plate and the molding layer.

10. The package structure according to claim 8, wherein the extension portion further comprises a through hole, and a part of the molding layer is located in the through hole.

11. The package structure according to claim 4, wherein the chip stack comprises at least two chips, and the at least two chips are fixed via a second adhesive layer.

12. The package structure according to claim 11, wherein a thickness of the first adhesive layer is less than a thickness of the second adhesive layer.
